(19) United States
(12) Patent Application Publication
(10) Pub. No.: US 2009/0057810 A1
(43) Pub. Date: Mar. 5, 2009

(54) Method of Fabricating an Integrated Circuit

(76) Inventors: Victor Verdugo, Dresden (DE); Dongping Wu, Dresden (DE); Clemens Fitz, Dresden (DE)

Correspondence Address: SLATER & MATSIL, L.L.P., 17950 PRESTON ROAD, SUITE 1000, DALLAS, TX, 75252, US

(21) Appl. No.: 11/850,440

(22) Filed: Sep. 5, 2007

(51) Int. Cl. H01L 21/8242; H01L 29/02

(52) U.S. Cl. 257/506; 438/241; 257/E21.646; 257/E29.001

(57) ABSTRACT

A method of fabricating an integrated circuit includes providing a semiconductor substrate having a doped area; generating a conductive structure towards the doped area, wherein the conductive structure includes an extending section that protrudes from the doped area; generating an electrically isolating layer at a sidewall of the extending section after generating the conductive structure.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A to 11B illustrate an embodiment of the invention; and

FIGS. 12A and 12B illustrate a second embodiment of the invention.

### DETAILED DESCRIPTION OF ILLUSTRATIVE EMBODIMENTS

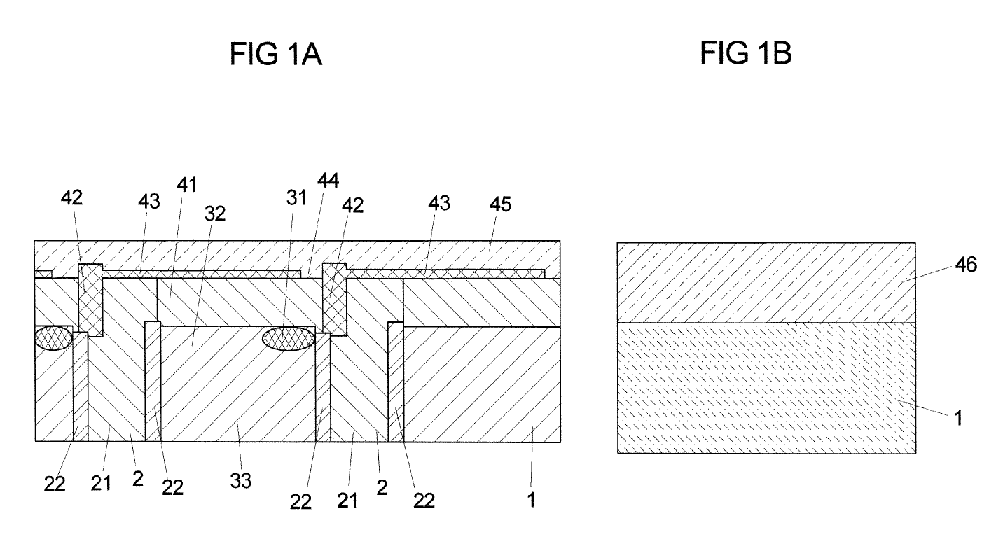

FIGS. 1A to 11A illustrate different steps during the production of a transistor which constitutes a part of a storage element belonging to a storage device of an integrated circuit. FIGS. 1B to 11B relate to the same steps depicting a support (peripheral) device of the storage device. Although an embodiment of the invention according to FIGS. 1A to 11B relate to producing a transistor as a part of a storage element of a storage device an embodiment of the invention is not restricted thereto but allows the fabrication of other integrated circuits such as logic devices or other electronic structures.

Referring to FIG. 1A a semiconductor substrate 1 (e.g., a silicon substrate) is depicted which is used to construct a plurality of storage elements. For this, substrate 1 comprises a plurality of capacitor structures 2 (e.g., deep trench capacitors) that each form part of a storage element. The capacitor structures 2 comprise a trench 21 filled with a conductive material (such as polysilicon) which is electrically isolated from neighboring structures by adjacent vertical isolating layers 22.

The semiconductor substrate 1 further comprises active areas each having a first and a second doped region of a first dopant type (e.g., p or n doped) as well as a third doped region in the form of a doped channel region 33 which extends between the first and the second doped region 31, 32. The channel regions 33 comprise a dopant of a second type which is different from the first type. The doped regions 31 to 33 each represent a source/drain region and a channel region, respectively, of a selection transistor for controlling the charging and discharging of one of the capacitors 2.

It is noted that the term “substrate” is not limited to the substrate material but also includes one or more layers which are arranged on the substrate material. As such the substrate 1 comprises a first conductive layer 41 (e.g., of polysilicon) which has vertical (i.e., perpendicular to the substrate surface) isolating regions 42 that will electrically isolate neighbouring storage elements. Further, a horizontal (i.e., parallel to the substrate surface) isolating region 43 is arranged on the first conductive layer 41, the horizontal isolating region 43 extending from the vertical isolating region 42 to the first doped region 31. More particularly, the isolating layer 43 ends at a distance to the vertical isolating region 42 of a neighboring storage element such that openings 44 are provided uncovering the first conductive layer 41 at the position of the first doped region 31.

A second conductive layer 45 which can be formed of the same material as the first conductive layer 41 (e.g., also made of polysilicon) is created above the first conductive layer 41, the second conductive layer 45 electrically connecting to the first conductive layer 41 through the openings 44.

Referring to FIG. 1B, the support device comprises a conductive layer 46 arranged on the substrate 1, wherein the substrate may be doped differently in the support device section than in the array device section.

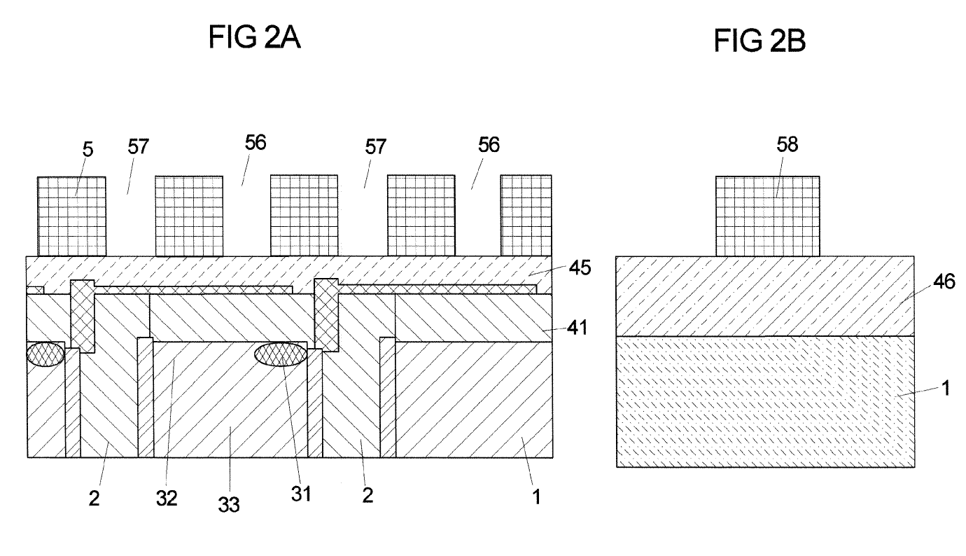

FIG. 2A illustrates that an auxiliary layer 5 is created on the conductive layer 45, the auxiliary layer 5 having a plurality of openings 56, 57, wherein the openings 56 are located at the position of the channel regions 33, while the openings 57 are located at the positions of the capacitors 2. The auxiliary layer 5 can consist of an isolating material such as silicon oxide or silicon nitride. However, in principle also non-isolating materials could be used. As to the support device the auxiliary layer provides a structure 58 on the conductive layer 46 (FIG. 2B).

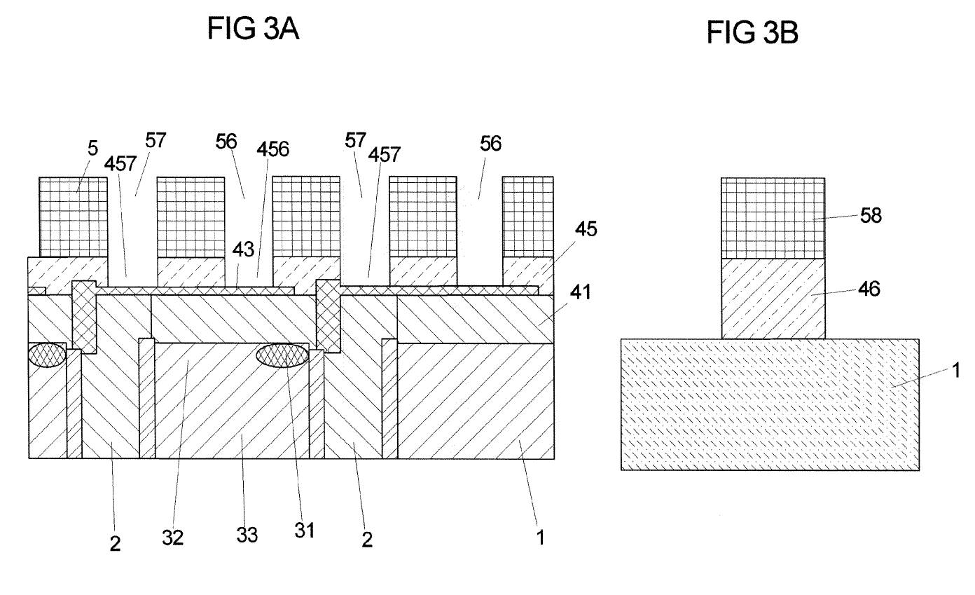

As shown in FIG. 3A, an etching step is performed using the openings 56, 57 of layer 5 such that corresponding openings 456 and 457 are created in the second conductive layer 45, the openings 456, 457 uncovering a portion of the horizontal isolating layer 43. At the same time the conductive layer 46 of the support device is etched in regions that are not covered by the structure 58. The result is shown in FIG. 3B.

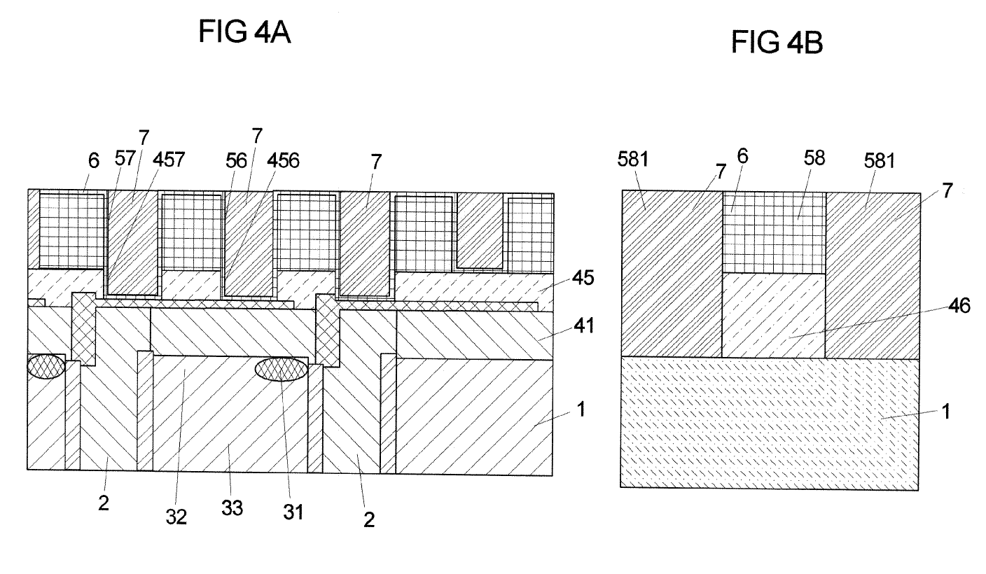

Referring to FIGS. 4A and 4B a (thin) isolating layer 6 (e.g., of a silicon nitride) is deposited such that the side walls and the bottom parts of the openings 56, 57, 456 and 457 are covered with the isolating layer 6. After the deposition of the layer 6 the openings 57, 457 and 56, 456 as well as regions 581 of the support device are filled with another isolating material 7 (e.g., silicon oxide) which is different from the material of the isolating layer 6. The filling with isolating material comprises the step of depositing the isolating material 7 and polishing the material back to auxiliary layer 5 (e.g., by chemical mechanical polishing).

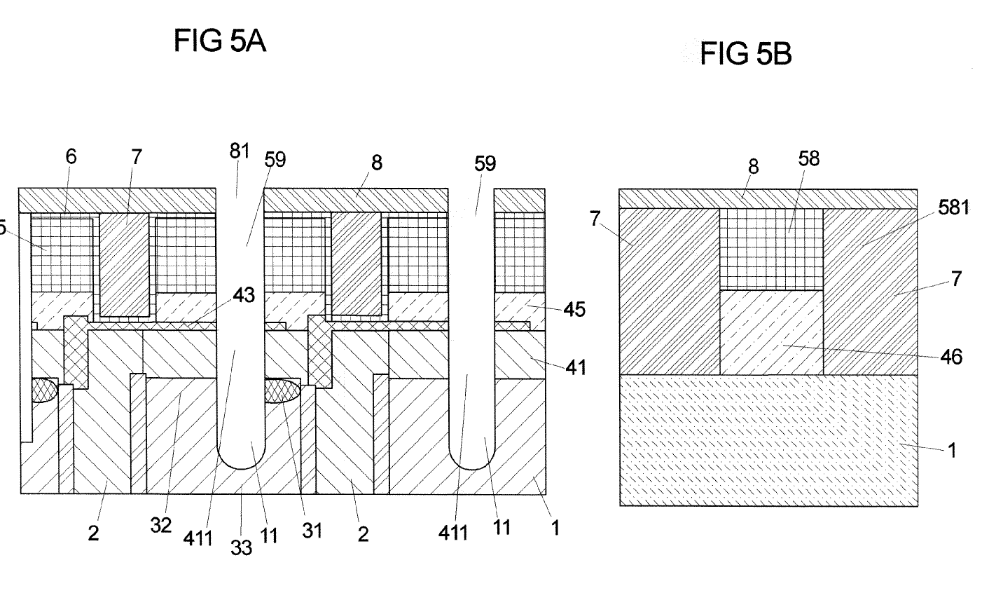

Further, according to FIGS. 5A and 5B, a mask layer 8 (e.g., formed of carbon) is deposited on the structure (on the auxiliary layer 5 and on the isolating layer 7, respectively), the mask layer 8 having an opening 81 which is used to create an opening 59 in the auxiliary layer 5 at the location of the third doped region 33, thereby removing the isolating material 7 of the openings 56. An etching step is then performed using the opening 59 in the auxiliary layer 5 such that an opening 411 through the first and second conductive layer 41, 45 (and through the horizontal isolating layer 43) is created as well as an opening 11 in the substrate 1.

The opening 11 in the substrate 1 is aligned with the opening 411 in the conductive layers 41, 45. The fabrication of the opening 59 in the auxiliary layer 5 and of the openings 411, 11 in the lower layers and the substrate can be performed using separate etching steps. It is, however, also possible to generate the openings 59, 411 and 11 by one etching step, e.g., without changing the etching tool or the etching means after having formed the opening in the auxiliary layer 5.

The production of the openings 411, 11 and 59 is part of producing an EUD device (Extended U-shaped Device) to contact the channel region 33. The openings 11, 411 constitute a recess channel through the gate conductor (the conductive layers 41, 45).

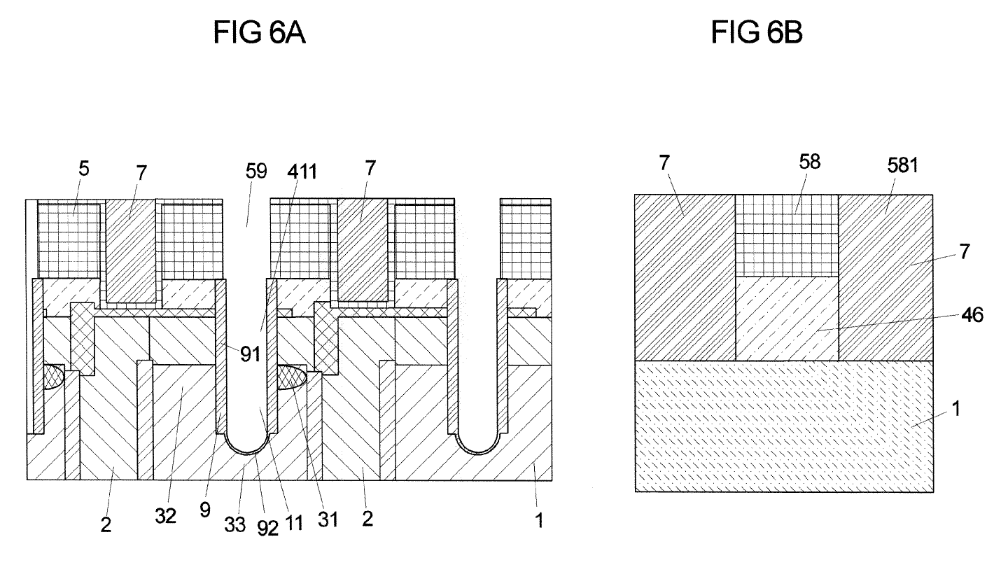

Referring to FIGS. 6A, 6B after completion of the U-shaped substrate opening 11 the mask layer 8 is removed. An isolating recess channel layer 9 is created having an upper part 91 that covers a sidewall portion of the opening 11 in the substrate 1 and the sidewalls of the opening 411 in the first and second conductive layer 41, 45. A lower portion 92 of the isolating layer 9 covers the bottom section of the opening 11.

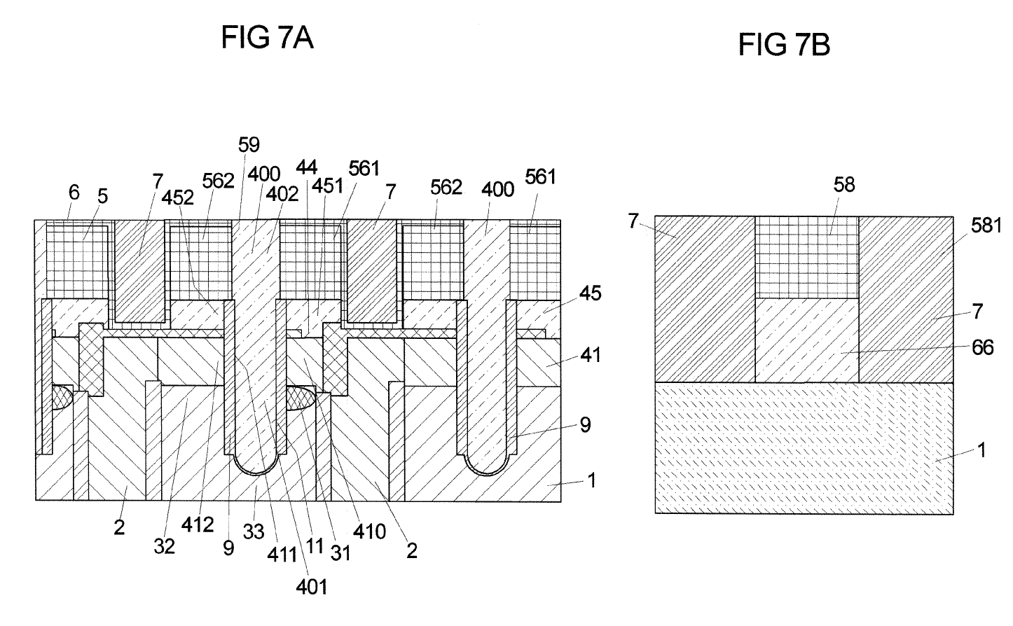

A conductive material is then deposited such that the opening 59 in the auxiliary layer 5 as well as the openings 411 and 11 are filled with the conductive material. The conductive material is polished back to the auxiliary layer (or to the thin isolating layer 6 still covering the auxiliary layer 5) such that a conductive structure 400 towards (connecting to) the third doped region 33 is formed through the openings 59, 411 and 11. This is shown in FIG. 7A. The conductive structure 400 comprises a lower section 401 that is limited by the substrate 1 and the first and second conductive layers 41, 45, respectively. Further, the conductive layer comprises an extending section in the form of an upper section 402 that extends beyond the substrate 1 (protrudes from the active area) and the conductive layers 41, 45 and that is limited by the auxiliary layer 5. More particularly, the upper section 402 is limited by structures 561 and 562 of layer 5.

Moreover, the conductive layer 41 comprises first structures (electrical structures) and second structures 410, 412 adjacent to the conductive structure 400 and the second conductive layer 45 also comprises first and second structures 451 and 452 adjacent to the conductive structure 400. The first structures 410 of the first conductive layer 41 and the first structure 451 of the second conductive layer 45 are electrically connected via the opening 44 and form an electrical contact to the first doped regions 31.

As further depicted in FIG. 7A, the recess channel isolating layer 9 isolates the lower section 401 of the conductive structure 400 from the adjacent sections of the substrate 1 and the conductive layers 41, 45, respectively.

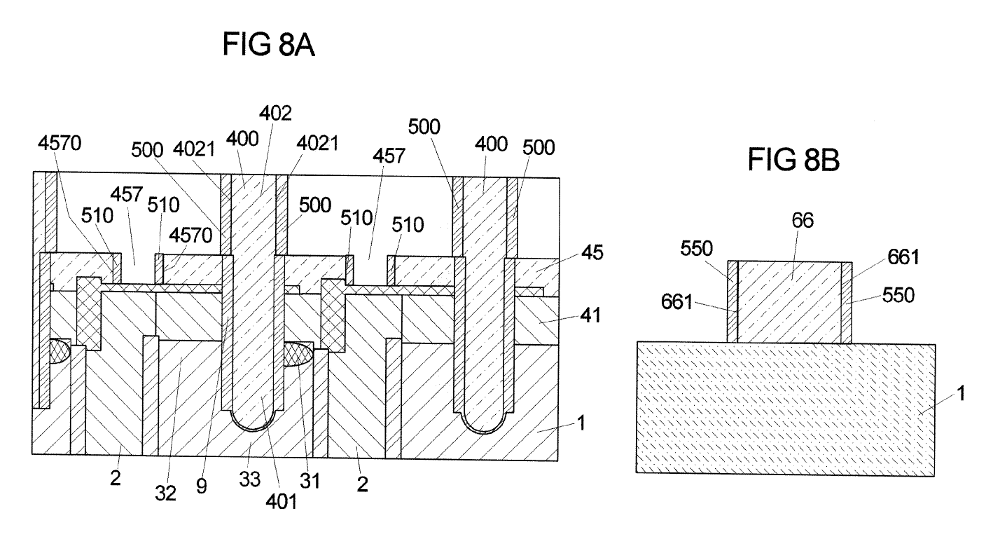

Referring to FIGS. 8A and 8B, the auxiliary layer 5 and the isolating layer 6 are removed in both the array section and the support section of the storage device. Due to the removal of the auxiliary layer the upper section 402 of the conductive structure 400 protrudes from the substrate and the conductive layers 41 and 45, wherein a sidewall 4021 of the upper section 402 is uncovered.

Further, the isolating material 7 is removed such that the openings 457 in the second conductive layer 45 are uncovered again. At the same time, the isolating structures 581 as well as the isolating parts 58 of the support device are removed (FIG. 8B).

After removal of the auxiliary layer 5 and the isolating material 7 an isolating layer in the form of a first spacer structure 500 is generated on the uncovered sidewalls 4021 of the upper section 402 of the conductive structure 400. In an example the spacer structures 500 are formed of silicon oxide which is generated thermally or by chemical vapour deposition in a self-aligned manner. Also, spacer structures 510 are generated at sidewalls 4570 of the openings 457 simultaneously with the generation of the spacers 500. Further, first spacer structures 550 are generated at sidewalls 661 of the conductive structure 66 of the support device simultaneously with the spacer structures of the storage elements (FIG. 8B).

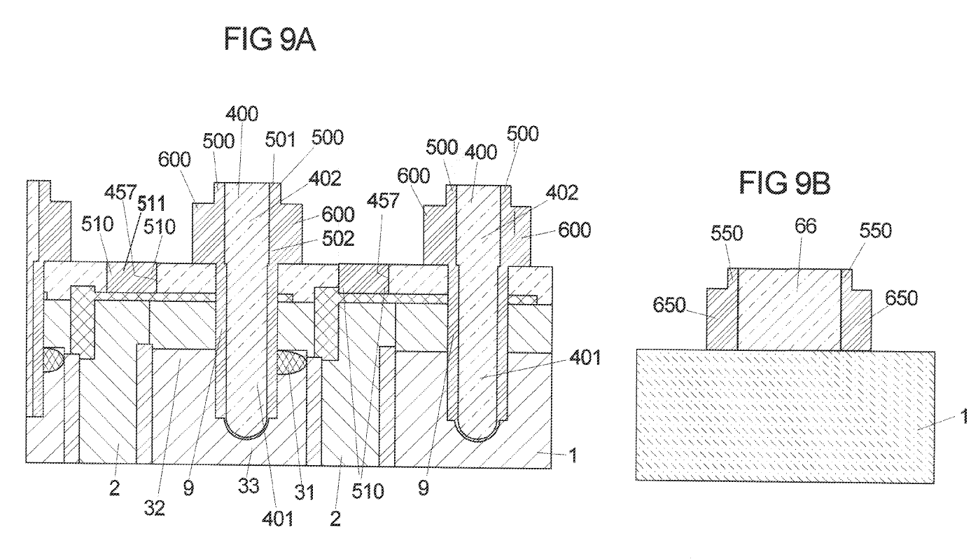

According to FIGS. 9A and 9B second spacer structures 600 are generated adjacent to the first spacer structures 500, wherein a lower portion 501 of the first spacer structures 500 is covered, whereas an upper portion 502 remains uncovered. Further, with the production of the second spacers 600 the openings 457 are completely filled with isolating material 511. Simultaneously with the second spacers 600 of the array device second spacer structures 650 are produced adjacent to the first spacer structures 550 of the support device (FIG. 9B).

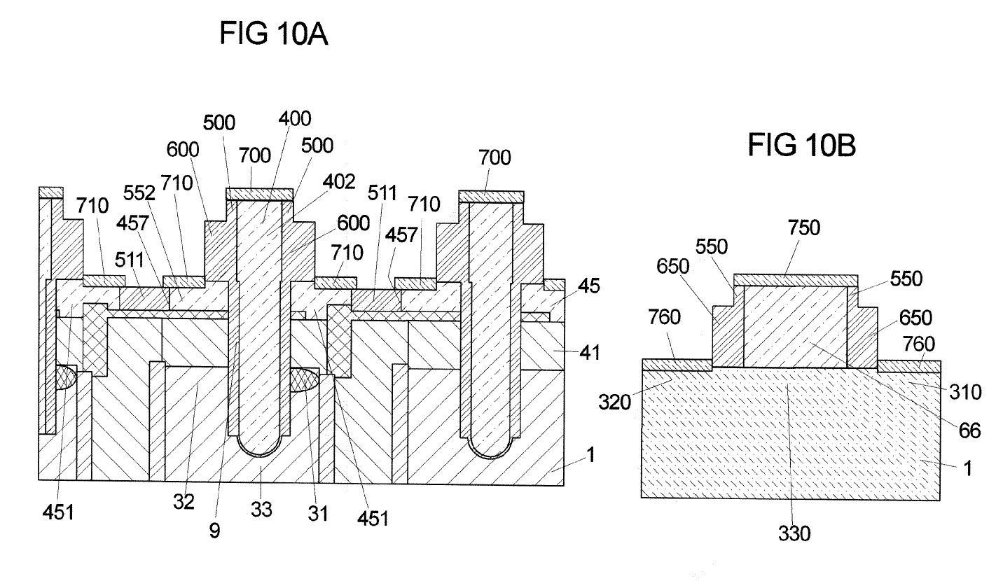

Referring to FIGS. 10A and 10B, first silicide layers 700 are created in a self-aligned manner (salicidation) on the upper sections 402 of the conductive structures 400 after having formed the first and second spacer structures 500, 600 and 550, 650, respectively. Further, second silicide layers 710 are created on the first structures 451 of the second (upper) conductive layer 45, wherein the first silicide layers 700 are spaced apart and thus are electrically isolated from the second silicide layers 710 by the first and second spacer structures 500, 600. The second silicide layers 710 extend from the second spacer structures 600 to the isolating material 511 (filling the openings 457). In another embodiment tungsten is deposited on the first structures 451 instead of the second silicide layers 710.

Referring to the support device, a first silicide layer 750 is created on the conductive part 66 and second silicide layers 760 are created adjacent to the second support device spacers 650 simultaneously with the first and second silicide layers of the array devices (the storage elements). The first and second silicide layers 750, 760 of the support device are separated by the first and second spacer structures 550, 650 such that they are electrically isolated from another. The second silicide layers 760 provide an electrical connection to underlying doped regions 310, 320 of the substrate. Moreover, the first silicide layer 750 is a part of a contact towards a channel region 330 of the support device. The first and second regions 310, 320 and the channel region 330 belong to an active area of a transistor of the support device.

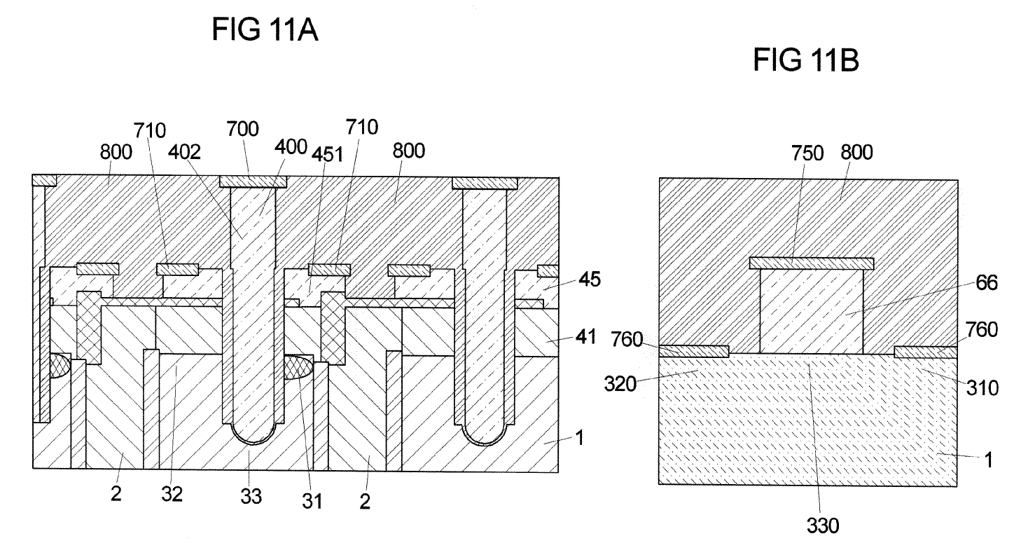

Referring to FIGS. 11A and 11B an isolating material 800 (e.g., silicon oxide) is deposited to cover the generated structures in particular between neighboring upper sections 402 of conductive structures 400 and between neighbouring structures of the support device. After depositing the isolating material 800 a polishing step is performed to polish back the isolating material to the height of the first silicide layers 700 on the conductive structures 400.

The plurality of storage elements formed by a storage capacitors 2 and a corresponding selection transistor (comprising doped regions 31 to 33) can be arranged in a non-regular or in a regular design, e.g., in a column and row design. Some of the first structures 451 (e.g., of one row or a column if the storage cells are arranged in a regular pattern) are electrically connected to each other such that they form a first conductive line (e.g., a bit line of the storage device). Similarly, some of the conductive structures 400 (in particular the upper sections 402) are electrically connected such that they form a second conductive line (e.g., a word line of the storage device) which, e.g., extends at an angle with respect to the first conductive line. Due to the protruding upper section 402 of the conductive structure 400 the second conductive line will extend above the first conductive line (word line over bit line concept).

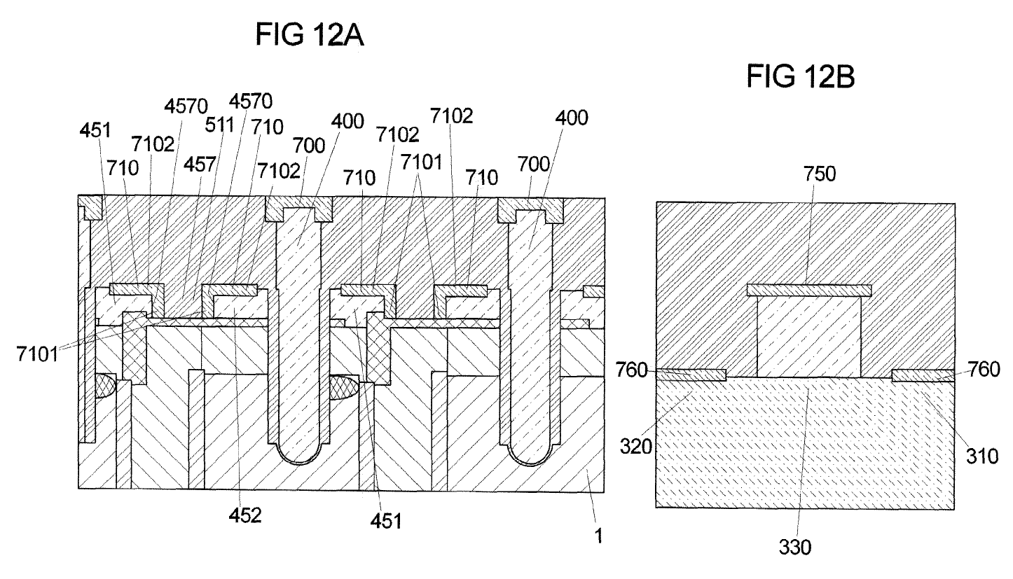

FIGS. 12A and 12B illustrate another embodiment of the invention is illustrated. Before the silicidation step in order to create first and second silicide layers 700, 710 the isolating material 511 (located in the opening 457 which is limited by the first structures 451 and structures 452 opposite to the structures 451) is recessed preferably at the sidewalls 4570 of the opening 457. Therefore, the subsequent silicidation of the first structures 451 and the opposite structures 452 results in second silicide layers 710 that each comprise a horizontal portion 7102 and a vertical portion 7101 which extends along a part of the sidewall 4570, i.e., the second silicide layers 710 have the form of an “L”.

It is noted that the invention is of course not limited to particular materials. The isolating layers in principle can be produced of any isolating material such as silicon oxide or silicon nitride. The material for the conductive structures or a conductive layer can be any conductive or semi-conductive material such as a metal or polysilicon. The silicide layer can be formed as a silicide of different materials, e.g., as cobald silicide. Further, the substrate material is not restricted to silicon, other materials, e.g., comprising gallium arsenide or indium phosphide can be used.

What is claimed is:

1. A method of fabricating an integrated circuit, the method comprising:
providing a substrate that comprises a doped area;
forming a conductive structure towards the doped area, wherein the conductive structure comprises an extending section that protrudes from the doped area; and
forming an electrically isolating layer at a sidewall of the extending section after generating the conductive structure.

2. The method according to claim 1, wherein the doped area is an active area comprising a first doped region, a second doped region and a third doped region that extends between the first and the second doped region.

3. The method according to claim 2, wherein the conductive structure is formed to extend towards the third doped region.

4. The method according to claim 1, wherein forming the conductive structure comprises:
providing an auxiliary layer, the auxiliary layer having an opening at the doped region;
performing an etching step using the opening of the auxiliary layer such that an opening in the substrate is created towards the doped region;
filling the opening in the substrate and the opening of the auxiliary layer with a conductive material such that the conductive structure towards the doped region is formed, wherein the extending section of the conductive structure is formed in the opening of the auxiliary layer; and
at least partially removing the auxiliary layer such that a sidewall of the extending section of the conductive structure is uncovered at which the isolating layer is formed.

5. The method according to claim 4, wherein:
the substrate comprises a conductive layer disposed below the auxiliary layer;
the conductive layer is structured using the opening of the auxiliary layer such that an opening is generated in the conductive layer before creating the opening in the substrate; and
the opening in the substrate, the opening in the conductive layer and the opening in the auxiliary layer are filled with the conductive material to create the conductive structure.

6. The method according to claim 5, further comprising forming another isolating layer at a sidewall of the opening in the conductive layer as well as at a sidewall and a bottom of the opening in the substrate before filling the openings with the conductive material such that a non-extending section of the conductive structure will be electrically isolated from adjacent structures.

7. The method according to claim 5, wherein the conductive layer comprises an electrical structure adjacent to the opening, the electrical structure being part of an electrical connection to the doped region.

8. The method according to claim 7, wherein the doped area comprises an active area comprising a first doped region, a second doped region and a third doped region that extends between the first and the second doped region and the electrical structure is a part of a connection to the first doped region.

9. The method according to claim 1, further comprising forming a silicide layer on the extending section of the conductive structure.

10. The method according to claim 7, wherein after removal of the auxiliary layer a first silicide layer is formed on the extending section of the conductive structure and a second silicide layer is formed on the electrical structure, wherein the isolating layer on the sidewall of the extending section provides an electrical isolation between the extending section and the second silicide layer.

11. The method according to claim 10, wherein the first and the second silicide layer are formed simultaneously.

12. The method according to claim 10, wherein a sidewall of the electrical structure is covered by an isolating layer such that the silicide layer is not created at the sidewall of the first structure.

13. The method according to claim 12, wherein at least a part of a sidewall of the electrical structure is uncovered such that the silicide layer is created on the top of the electrical structure and at least a part of the uncovered part of the sidewall.

14. The method according to claim 9, wherein the silicide layer is created in the form of self-aligned silicide (salicide) layers.

15. The method according to claim 7, wherein a tungsten layer is created on the electrical structure after removal of the auxiliary layer.

16. The method according to claim 4, wherein the bottom region of the opening in the substrate is U-shaped.

17. The method according to claim 2, wherein the dopant of the first and the second doped region is of a first type and the dopant of the third doped region is of a second type which is different from the first type.

18. The method according to claim 17, wherein the first region constitutes a source or a drain region of a transistor, the second region correspondingly constitutes a drain or a source region of the transistor and the third region constitutes a channel region of the transistor.

19. The method according to claim 18, wherein the integrated circuit comprises a storage device and the transistor is a selection transistor of a storage element of the storage device.

20. The method according to claim 18, wherein a plurality of transistors of a plurality of storage elements is fabricated using the method of claim 18, wherein a first conductive line is formed which electrically connects to at least some of the electrical structures of transistors and a second conductive line is formed which electrically connects to at least some of the conductive structures of the transistors.

21. The method according to claim 20, wherein a distance between the second conductive line and the substrate is larger than the distance between the first conductive line and the substrate.

22. The method according to claim 19, wherein the storage device comprises at least one support device that interacts with at least one storage element, the support device comprising a transistor that is formed simultaneously with the selection transistor of the storage element.

23. The method according to claim 22, wherein
the transistor of the support device comprises first and second doped regions of a first type and third doped regions of a second type different from the first type,
a contact structure is formed towards the third doped region of the support device transistor; and
an isolating layer is formed on a sidewall of the contact structure simultaneously with the formation of the sidewall layer of the selection transistors.

24. The method according to claim 23, wherein a silicide layer is formed on the contact structure of the support device, the silicide layer being formed simultaneously with the formation of a silicide layer on the conductive structure of the transistor of the storage element.

25. The method according to claim 24, wherein
a first and a second structure adjacent to the support device contact structure provide electrical connections to the first and second doped regions, respectively, and
a silicide layer is created on the first and second structure simultaneously with the formation of the silicide layer on the support device contact structure,
the isolating layer providing an electrical isolation between the silicide layers on the first and second structures of the support device and the silicide layer on the support device contact structure.

26. An integrated circuit, comprising
a substrate having a doped area;
a conductive structure towards the doped area, wherein the conductive structure comprises an extending section that protrudes from the doped region; and
an electrically isolating layer at a sidewall of the extending section.
